(19) United States
(12) Patent Application Publication
(10) Pub. No.: US 2025/0391778 A1
(43) Pub. Date: Dec. 25, 2025

(54) SEMICONDUCTOR CHIP AND SEMICONDUCTOR PACKAGE INCLUDING THE SAME

(71) Applicant: Samsung Electronics Co., Ltd., Suwon-si (KR)

(72) Inventors: Hyunsoo CHUNG, Suwon-si (KR); Kwang-Soo KIM, Suwon-si (KR)

(73) Assignee: Samsung Electronics Co., Ltd., Suwon-si (KR)

(21) Appl. No.: 19/010,759

(22) Filed: Jan. 6, 2025

(30) Foreign Application Priority Data
Jun. 25, 2024 (KR) 10-2024-0082919

(51) Int. Cl. H01L 23/538; H01L 23/00; H01L 23/29; H01L 23/373; H01L 25/07; H01L 25/11

(52) U.S. Cl. CPC H01L 23/5384; H01L 23/3738; H01L 24/08; H01L 25/074; H01L 23/293; H01L 25/117; H01L 2224/08146; H01L 2224/08235; H01L 2225/06541; H01L 2225/06565; H01L 2225/107; H01L 2225/1094

(57) ABSTRACT

A semiconductor package includes a first semiconductor chip and second semiconductor chips. The first semiconductor chip includes a first semiconductor substrate, first through-electrodes, a power wiring pattern connected to a portion of the first through-electrodes, and a compensation layer disposed on the first semiconductor substrate. The second semiconductor chips are disposed on the first semiconductor chip, each including a second semiconductor substrate. The compensation layer includes a compensation substrate, and a compensation through-electrodes that are electrically connected to a portion of the first through-electrodes, each second semiconductor chip includes second through-electrodes, and a portion of the first through-electrodes are electrically connected to a portion of the second through-electrodes through the compensation through-electrodes.

### CROSS-REFERENCE TO RELATED APPLICATION

This application claims priority to Korean Patent Application No. 10-2024-0082919, filed in the Korean Intellectual Property Office on Jun. 25, 2024, the entire contents of which being hereby incorporated by reference.

### BACKGROUND

The present disclosure relates to a semiconductor chip and a semiconductor package.

Along with the development of semiconductor technology, semiconductor devices have higher capacity and integration density. While these technological advances have greatly improved the performance of various electronic devices, the heat dissipation performance of semiconductor devices is emerging as an important challenge.

If heat generated by a semiconductor device is not dissipated properly, electrical characteristics of the semiconductor device may change, which may result in slower or less reliable data processing. Furthermore, if heat is continuously accumulated in the semiconductor device, the semiconductor device may be physically damaged and malfunction. This accumulation of heat and resulting damage and/or malfunction can reduce the performance, lifetime, and reliability of an electronic system including the semiconductor device.

### SUMMARY

It is an aspect to provide a semiconductor chip, and a semiconductor package with improved heat dissipation.

According to an aspect of one or more embodiments, there is provided a semiconductor package comprising a first semiconductor chip comprising a first semiconductor substrate having an active side and an inactive side opposite to the active side, a plurality of first through-electrodes penetrating the first semiconductor substrate, a power wiring pattern disposed on the inactive side of the first semiconductor substrate and connected to at least a portion of the plurality of first through-electrodes, and a compensation layer disposed on the active side of the first semiconductor substrate; and a plurality of second semiconductor chips disposed on the first semiconductor chip, each of the plurality of second semiconductor chips comprising a second semiconductor substrate. The compensation layer comprises a compensation substrate, and a compensation through-electrodes that penetrate the compensation substrate and that are electrically connected to at least a portion of the plurality of first through-electrodes, each of the plurality of second semiconductor chips comprises a plurality of second through-electrodes that penetrate the second semiconductor substrate, and at least a portion of the plurality of first through-electrodes is electrically connected to at least a portion of the plurality of second through-electrodes through the compensation through-electrodes.

According to another aspect of one or more embodiments, there is provided a semiconductor package comprising a first semiconductor chip comprising a first semiconductor substrate having an active side and an inactive side opposite to the active side, a plurality of first through-electrodes penetrating the first semiconductor substrate, a power wiring pattern disposed on the inactive side of the first semiconductor substrate and connected to at least a portion of the plurality of first through-electrodes, and a compensation layer disposed on the active side of the first semiconductor substrate; a plurality of second semiconductor chips disposed on the first semiconductor chip, each of the plurality of second semiconductor chips comprising a second semiconductor substrate; and a first inter-chip bonding layer between the first semiconductor chip and the plurality of second semiconductor chips. The compensation layer comprises a compensation substrate, and compensation through-electrodes that penetrate the compensation substrate and that are electrically connected to at least a portion of the plurality of first through-electrodes, each of the plurality of second semiconductor chips comprises a plurality of second through-electrodes that penetrate the second semiconductor substrate. The first inter-chip bonding layer comprises first inter-chip connection members that electrically connect the compensation through-electrodes to at least a portion of the plurality of second through-electrodes; and a first inter-chip insulating layer surrounding the first inter-chip connection members, and at least a portion of the plurality of first through-electrodes is electrically connected to at least a portion of the plurality of second through-electrodes through the compensation through-electrodes and the first inter-chip connection members.

According to yet another aspect of one or more embodiments, there is provided a semiconductor chip comprising a semiconductor substrate having an active side and an inactive side opposite to the active side; a plurality of through-electrodes penetrating the semiconductor substrate; a power wiring pattern disposed on the inactive side of the semiconductor substrate and connected to at least a portion of the plurality of through-electrodes; and a compensation layer disposed on the active side of the semiconductor substrate, wherein the compensation layer comprises a compensation substrate, and compensation through-electrodes that penetrate the compensation substrate and that are electrically connected to at least a portion of the plurality of through-electrodes.

### BRIEF DESCRIPTION OF THE DRAWINGS

The above and other aspects will be described with reference to the accompanying drawings, in which:

FIGS. 1 to 3 are diagrams illustrating an example of a semiconductor package according to some embodiments;

FIGS. 4 to 13 are diagrams illustrating an example of a process of manufacturing a first semiconductor chip, according to some embodiments;

FIGS. 14 to 21 are diagrams illustrating an example of a process of manufacturing a semiconductor package, according to some embodiments;

FIGS. 22 to 27 are diagrams illustrating an example of a process of manufacturing a semiconductor package according to some embodiments;

FIG. 28 is a diagram illustrating an example of a semiconductor package, according to some embodiments;

FIG. 29 is a diagram illustrating an example implementation of a semiconductor package, according to some embodiments; and

FIG. 30 is a diagram illustrating an example of a semiconductor package, according to some embodiments.

### DETAILED DESCRIPTION

Specific details for implementing various embodiments consistent with the present disclosure will be described in detail with reference to the accompanying drawings. In the drawings, similar reference numerals indicated similar elements, but are not limited thereto, and in some cases repeated description thereof may omitted for clarity and conciseness of description of the various embodiments. Moreover, in the following description, detailed descriptions of well-known functions or configurations will be omitted if such descriptions would make the subject matter of the present disclosure rather unclear.

According to various embodiments described below, a thickness of a substrate of a semiconductor chip can be reinforced due to a compensation layer, which may supplement heat dissipation performance of the semiconductor chip or a semiconductor package including the semiconductor chip.

According to various embodiments described below, normal semiconductor chips among the semiconductor chips from the diced wafer can be selected and rearranged and packaged, thereby improving the yield of the semiconductor package.

The advantages of the various embodiments are not limited to the advantages described above, and other advantages not described herein can be clearly understood by those of ordinary skill in the art from the description and appended claims.

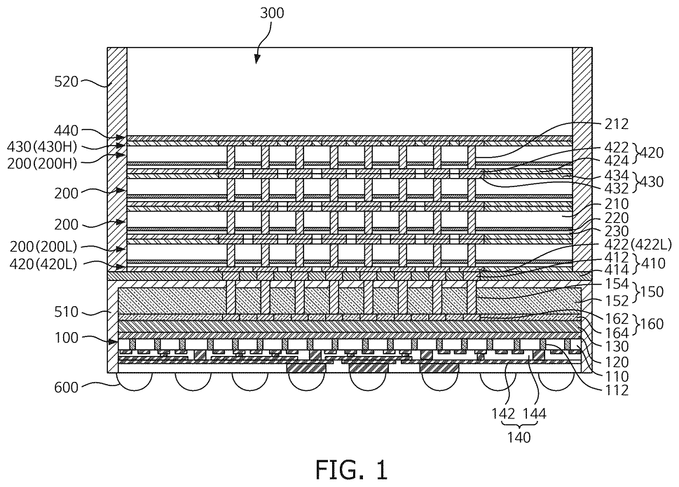

FIGS. 1 to 3 are diagrams illustrating an example of a semiconductor package according to some embodiments.

Referring to FIG. 1, a semiconductor package may include a first semiconductor chip 100 and a plurality of second semiconductor chips 200 disposed on the first semiconductor chip 100 in a stacking direction. Although FIG. 1 illustrates that the semiconductor package includes four second semiconductor chips 200 stacked on the first semiconductor chip 100, embodiments are not limited thereto and, in some embodiments, the semiconductor package may include any number (two or more) of second semiconductor chips 200.

The first semiconductor chip 100 may include a first semiconductor substrate 110, a plurality of first through-electrodes 112 penetrating the first semiconductor substrate 110, a first device layer 120, a signal wiring layer 130, and a power wiring layer 140.

For example, the first semiconductor substrate 110 may include silicon (Si) or germanium (Ge), but embodiments are not limited thereto. For example, the first semiconductor substrate 110 may include a material having properties similar to silicon or germanium, such as silicon germanium (SiGe), indium antimonide (InSb), lead telluride compound (PbTe), indium arsenide (InAs), indium phosphide (InP), gallium arsenide (GaAs), gallium antimonide (GaSb), etc. The first semiconductor substrate 110 may include a conductive region such as, for example, a well that is doped with impurities.

The first device layer 120 may be formed on one side of the first semiconductor substrate 110. The first device layer 120 may include a semiconductor device. The first device layer 120 may include various microelectronic devices, for example, a metal-oxide-semiconductor field effect transistor (MOSFET) such as a complementary metal-oxide-semiconductor (CMOS) transistor, system large scale integration (LSI), flash memory, DRAM, SRAM, EEPROM, PRAM, MRAM, or RERAM, an imaging sensor such as a CMOS imaging sensor (CIS), a micro-electro-mechanical system (MEMS), an active device, a passive device, etc. The one side of the first semiconductor substrate 110 on which the first device layer 120 is formed may be referred to as an active side (or a front side) of the first semiconductor substrate 110, and the other side of the first semiconductor substrate 110 opposite to the active side may be referred to as an inactive side (or a back side) of the first semiconductor substrate 110.

The signal wiring layer 130 of the first semiconductor chip 100 may be disposed on the active side of the first semiconductor substrate 110. For example, the signal wiring layer 130 of the first semiconductor chip 100 may be disposed on the first device layer 120. Although not illustrated in the drawings for convenience of description, in some embodiments, the signal wiring layer 130 may include a signal wiring pattern through which signals are transferred, and a signal wiring insulating layer surrounding the signal wiring pattern. The signal wiring pattern may be electrically connected to at least a portion of the semiconductor device of the first device layer 120 and/or at least a portion of the plurality of first through-electrodes 112. That is, the at least a portion of the plurality of first through-electrodes 112 may be electrically connected to the signal wiring pattern of the signal wiring layer 130 and used for transferring signals.

The power wiring layer 140 of the first semiconductor chip 100 may be disposed on the inactive side of the first semiconductor substrate 110. The power wiring layer 140 may include a power wiring pattern 142 through which power (e.g., power, ground, etc.) is transferred and a power wiring insulating layer 144 surrounding the power wiring pattern 142. The power wiring pattern 142 may be electrically connected to at least a portion of the semiconductor device of the first device layer 120 and/or at least a portion of the plurality of first through-electrodes 112. In an embodiment, the power wiring layer 140 may configure a back-side power delivery network (BSPDN). In this case, the power wiring pattern 142 may be electrically connected to the semiconductor device of the first device layer 120 through a first through-electrode 112 and a buried power rail (not illustrated) may be electrically connected to the first through-electrode 112. That is, at least a portion of the plurality of first through-electrodes 112 may be electrically connected to the power wiring pattern 142 of the power wiring layer 140 and used for transferring power. The arrangement, number of layers, number of the power wiring patterns 142 illustrated in FIG. 1, etc. are only examples, and embodiments are not limited thereto.

In an embodiment, the first semiconductor chip 100 may further include a redistribution layer disposed on the signal wiring layer 130 and/or the power wiring layer 140.

The first semiconductor chip 100 may further include a compensation layer 150. The compensation layer 150 may be disposed on the active side of the first semiconductor substrate 110. For example, in some embodiments, the compensation layer 150 may be disposed on the signal wiring layer 130 of the first semiconductor chip 100. In a case in which the redistribution layer is disposed on the signal wiring layer 130 of the first semiconductor chip 100, the compensation layer 150 may be disposed on the redistribution layer.

The compensation layer 150 may include a compensation substrate 152 and a compensation through-electrode 154 penetrating the compensation substrate 152. In some embodiments, the compensation layer 150 may include a plurality of the compensation through-electrodes 154. In some embodiments, the compensation substrate 152 may include the same or similar material as or to the material included in the first semiconductor substrate 110, such as silicon, germanium, etc. In some embodiments, the compensation substrate 152 may include a material having a higher thermal conductivity than a material (e.g., silicon, germanium, etc.) generally included in a semiconductor substrate. A thickness of the compensation substrate 152 in the stacking direction may be greater than a thickness of the first semiconductor substrate 110. The thickness of the substrate of the first semiconductor chip 100 in the stacking direction may be reinforced due to the compensation layer 150, which may supplement the heat dissipation performance of the first semiconductor chip 100 or the semiconductor package including the first semiconductor chip 100.

The compensation through-electrodes 154 penetrating the compensation substrate 152 may be electrically connected to at least a portion of the plurality of first through-electrodes 112 and at least a portion of a plurality of second through-electrodes 212 of a second semiconductor chip 200. That is, the at least a portion of the plurality of first through-electrodes 112 of the first semiconductor chip 100 may be electrically connected to the at least a portion of the plurality of second through-electrodes 212 of the second semiconductor chip 200 through the compensation through-electrode 154.

In some embodiments, a width of the compensation through-electrode 154 in a direction orthogonal to the stacking direction may be greater than a width of at least one of the plurality of first through-electrodes 112 or a width of at least one of the plurality of second through-electrodes 212. In some embodiments, a length of the compensation through-electrode 154 in the stacking direction may be greater than a length of at least one of the plurality of first through-electrodes 112 or a length of at least one of the plurality of second through-electrodes 212. With the compensation through-electrode 154 formed longer and/or wider than typical through-electrodes, signal transfer and/or power transfer between the first semiconductor chip 100 and the plurality of second semiconductor chips 200 can be facilitated.

In some embodiments, the first semiconductor chip 100 may further include an in-chip bonding layer 160 interposed between the compensation layer 150 and the first semiconductor substrate 110. The in-chip bonding layer 160 may include an in-chip connection member 162 and an in-chip insulating layer 164. In some embodiments, the in-chip bonding layer 160 may include a plurality of the in-chip connection members 162. The in-chip connection members 162 may electrically connect the compensation through-electrodes 154 to at least a portion of the plurality of first through-electrodes 112. The in-chip insulating layer 164 may surround the in-chip connection member 162. In an embodiment, the plurality of first through-electrodes 112 may be electrically connected to the compensation through-electrodes 154 through the in-chip connection members 162.

The in-chip bonding layer 160 may be formed by various bonding methods. For example, the in-chip bonding layer 160 may be formed by a hybrid bonding method. In the hybrid bonding method, bonding pads facing each other may be expanded thermally to come into contact with each other, and metal atoms contained in the bonding pads may diffuse to bond, thereby forming the in-chip connection member 162. In the hybrid bonding method, layers of insulating material facing each other may be expanded thermally to come into contact with each other, and atoms contained in the layers of insulating material may diffuse to bond, thereby forming the in-chip insulating layer 164. If the in-chip bonding layer 160 is formed by the hybrid bonding method, a thickness of the in-chip bonding layer 160 may be thinner compared with comparative examples.

Within the semiconductor package, the first semiconductor chip 100 may be disposed such that the active side of the first semiconductor substrate 110 faces upwards and the inactive side of the first semiconductor substrate 110 faces downwards. In other words, the active side of the first semiconductor substrate 110 may face upwards towards the second semiconductor chips 200. However, embodiments are not limited thereto and, in some embodiments, the first semiconductor chip 100 may be disposed such that the active side of the first semiconductor substrate 110 faces downwards and the inactive side of the first semiconductor substrate 110 faces upwards.

The plurality of second semiconductor chips 200 may be disposed on the first semiconductor chip 100. For example, the plurality of second semiconductor chips 200 may be sequentially stacked on the first semiconductor chip 100. In this description, a second semiconductor chip disposed at a lowermost end in the stacking direction among the plurality of second semiconductor chips 200 may be referred to as a lowermost second semiconductor chip 200L, and a second semiconductor chip disposed at an uppermost end in the stacking direction may be referred to as an uppermost second semiconductor chip 200H. Each of the plurality of second semiconductor chips 200 may include a second semiconductor substrate 210, the plurality of second through-electrodes 212 penetrating the second semiconductor substrate 210, a second device layer 220, and a wiring layer 230.

The second semiconductor substrate 210 may include the same or similar material as or to the material of the first semiconductor substrate 110. The second device layer 220 may be formed on one side of the second semiconductor substrate 210. The second device layer 220 may include a semiconductor device. For example, the second device layer 220 may include various microelectronic devices described above that may be included in the first device layer 120. The one side of the second semiconductor substrate 210 on which the second device layer 220 is formed may be referred to as an active side (or a front side) of the second semiconductor substrate 210, and the other side of the second semiconductor substrate 210 opposite to the active side may be referred to as an inactive side (or a back side) of the second semiconductor substrate 210.

The wiring layer 230 of the second semiconductor chip 200 may be disposed on the active side of the second semiconductor substrate 210. For example, the wiring layer 230 of the second semiconductor chip 200 may be disposed on the second device layer 220. Although not illustrated, in some embodiments, the wiring layer 230 of the second semiconductor chip 200 may include a wiring pattern through which signals and/or power are transferred, and a wiring insulating layer surrounding the wiring pattern. The wiring pattern may be electrically connected to at least a portion of the semiconductor device of the second device layer 220 and/or at least a portion of the plurality of second through-electrodes 212. In an embodiment, the second semiconductor chip 200 may further include a redistribution layer disposed on the wiring layer 230.

Within the semiconductor package, each of the plurality of second semiconductor chips 200 may be disposed such that the active side of the second semiconductor substrate 210 faces downwards towards the first semiconductor chip 100 and the inactive side of the second semiconductor substrate 210 faces upwards. For example, in an embodiment, within the semiconductor package, each of the plurality of second semiconductor chips 200 may be disposed such that the active side of the second semiconductor substrate 210 faces the active side of the first semiconductor chip 100. However, embodiments are not limited thereto and, in some embodiments, each of the plurality of second semiconductor chips 200 may also be disposed such that the active side of the second semiconductor substrate 210 faces upwards and the inactive side of the second semiconductor substrate 210 faces downwards.

Each of the plurality of second through-electrodes 212 penetrating the second semiconductor substrate 210 may be electrically connected to at least a portion of the plurality of second through-electrodes 212 of another second semiconductor chip 200 and/or at least a portion of the plurality of first through-electrodes 112. For example, the plurality of second through-electrodes 212 included in each of the plurality of second semiconductor chips 200 may be electrically connected to the plurality of second through-electrodes 212 included in an adjacent second semiconductor chip 200. In an embodiment, at least a portion of the plurality of second through-electrodes 212 included in the lowermost second semiconductor chip 200L may be electrically connected to the plurality of first through-electrodes 112 included in the first semiconductor chip 100.

First inter-chip bonding layers 410 and 420L may be interposed between the first semiconductor chip 100 and the plurality of second semiconductor chips 200. The first inter-chip bonding layers 410 and 420L may include first inter-chip connection members 412 and 422L and first inter-chip insulating layers 414 and 424 surrounding the first inter-chip connection members 412 and 422L, respectively. The first inter-chip connection members 412 and 422L may electrically connect the compensation through-electrodes 154 to at least a portion of the plurality of second through-electrodes 212 (e.g., at least a portion of the plurality of second through-electrodes 212 included in the lowermost second semiconductor chip 200L). That is, at least a portion of the plurality of first through-electrodes 112 and at least a portion of the plurality of second through-electrodes 212 may be electrically connected to each other through the compensation through-electrodes 154 and the first inter-chip connection members 412 and 422L.

The first inter-chip bonding layers 410 and 420L that face each other may be referred to as a first bonding layer and a second bonding layer, respectively. The first inter-chip bonding layers 410 and 420L may be coupled or connected together by coupling or connecting the first bonding layer 410 and the second bonding layer 420L that face each other. For example, the first bonding layer 410 may be formed above the first semiconductor chip 100, and the first bonding layer 410 may include a first bonding pad 412 and a first insulating layer 414 surrounding the first bonding pad 412. The second bonding layer 420L may be formed below the lowermost second semiconductor chip 200L, and the second bonding layer 420L may include a second bonding pad 422L and a second insulating layer 424 surrounding the second bonding pad 422L. The first inter-chip bonding layers 410 and 420L may be coupled or connected together by coupling or connecting the first bonding layer 410 formed above the first semiconductor chip 100 to the second bonding layer 420L formed below the lowermost second semiconductor chip 200L.

In an embodiment, the first inter-chip bonding layers 410 and 420L may be coupled together by coupling the first bonding layer 410 to the second bonding layer 420L using the hybrid bonding method described above. That is, the first inter-chip connection members 412 and 422L may be coupled together by diffusion bonding the first bonding pad 412 and the second bonding pad 422L, and the first inter-chip insulating layers 414 and 424 may be coupled together by diffusion bonding the first insulating layer 414 and the second insulating layer 424.

In some embodiments, the first inter-chip bonding layers 410 and 420L may be connected together by connecting the first bonding layer 410 to the second bonding layer 420L using a thermo-compression bonding (TCB) method. In the TCB method, a separate connection member (e.g., a bump) may be interposed between the first bonding pad 412 and the second bonding pad 422L, and the space surrounding the connection member may be filled with an insulating member or a molding member as described below.

Second inter-chip bonding layers 420 and 430 may be interposed between the plurality of second semiconductor chips 200. In some embodiments, a second inter-chip bonding layers 420 and 430 may be disposed between each adjacent two of the plurality of second semiconductor chips 200, as illustrated in FIG. 1. The second inter-chip bonding layers 420 and 430 may include second inter-chip connection members 422 and 432 and second inter-chip insulating layers 424 and 434 surrounding the second inter-chip connection members 422 and 432, respectively. The second inter-chip connection members 422 and 432 may electrically connect the plurality of second through-electrodes 212 of two adjacent second semiconductor chips 200 among the plurality of second semiconductor chips 200 to each other. That is, the plurality of second through-electrodes 212 included in the two adjacent second semiconductor chips 200 may be electrically connected to each other through the second inter-chip connection members 422 and 432.

The second inter-chip bonding layers 420 and 430 that face each other may be referred to as a second bonding layer and a third bonding layer, respectively. The second inter-chip bonding layers 420 and 430 may be coupled or connected together by coupling or connecting the second bonding layer 420 and the third bonding layer 430 that face each other. For example, the second bonding layer 420 may be formed below each of the plurality of second semiconductor chips 200. Each of the second bonding layers 420 may include a second bonding pad 422 electrically connected to the plurality of second through-electrodes 212 included in the second semiconductor chip 200 disposed above the second bonding layer 420, and the second insulating layer 424 surrounding the second bonding pad 422. The third bonding layer 430 may be formed above each of the plurality of second semiconductor chips 200. Each of the third bonding layers 430 may include a third bonding pad 432 electrically connected to the plurality of second through-electrodes 212 included in the second semiconductor chip 200 disposed below the third bonding layer 430, and a third insulating layer 434 surrounding the third bonding pad 432. The second inter-chip bonding layers 420 and 430 may be coupled or connected together by coupling or connecting the second bonding layer 420 formed below an upper second semiconductor chip 200 among the two adjacent second semiconductor chips 200, and the third bonding layer 430 formed above a lower second semiconductor chip 200 among the two adjacent second semiconductor chips 200.

In an embodiment, the second inter-chip bonding layers 420 and 430 may be coupled together by coupling the second bonding layer 420 to the third bonding layer 430 using the hybrid bonding method described above. That is, the second inter-chip connection members 422 and 432 may be coupled together by diffusion bonding the second bonding pad 422 and the third bonding pad 432, and the second inter-chip insulating layers 424 and 434 may be coupled together by diffusion bonding the second insulating layer 424 and the third insulating layer 434.

In some embodiments, the second inter-chip bonding layers 420 and 430 may be connected together by connecting the second bonding layer 420 to the third bonding layer 430 using the thermo-compression bonding (TCB) method. In the TCB method, a separate connection member may be interposed between the second bonding pad 422 and the third bonding pad 432, and the space surrounding the connection member may be filled with an insulating member or a molding member as described below.

The semiconductor package may further include an upper dummy chip 300 disposed on the plurality of second semiconductor chips 200. For example, the semiconductor package may include the upper dummy chip 300 disposed on the uppermost second semiconductor chip 200H. In some embodiments, the upper dummy chip 300 may include the same or similar material as or to the material (e.g., silicon, germanium, etc.) included in the first semiconductor substrate 110 and the second semiconductor substrate 210. In some embodiments, the upper dummy chip 300 may include only the same or similar material (e.g., silicon, germanium, etc.) as or to the material included in the first semiconductor substrate 110 and the second semiconductor substrate 210. For example, in an embodiment, the upper dummy chip 300 may be at least a portion of a bare wafer.

Third inter-chip bonding layers 430H and 440 that face each other may be referred to as a third bonding layer and a fourth bonding layer, respectively. The inter-chip bonding layers 430H and 440 may be interposed between the uppermost second semiconductor chip 200H and the upper dummy chip 300. The third inter-chip bonding layers 430H and 440 may insulate the uppermost second semiconductor chip 200H from the upper dummy chip 300. The third inter-chip bonding layers 430H and 440 may be coupled or connected together by coupling or connecting the third bonding layer 430H and the fourth bonding layer 440 that face each other. For example, the third bonding layer 430H including the third insulating layer 434 may be formed above the uppermost second semiconductor chip 200H, and the fourth bonding layer 440 including an insulating material may be formed below the upper dummy chip 300. The third inter-chip bonding layers 430H and 440 may be coupled or connected together by coupling or connecting the third bonding layer 430 and the fourth bonding layer 440 using any bonding method such as diffusion bonding, thermo-compression bonding, etc.

In some embodiments, wiring patterns and connection members (e.g., bonding pads) included in the semiconductor package may include a metallic material such as copper (Cu), aluminum (Al), or tungsten (W). The wiring patterns may include a barrier layer for wiring and a metal layer for wiring. The barrier layer for wiring may include, for example, a metal, a metal nitride, or an alloy thereof, and the metal layer for wiring may include, for example, at least one metal selected from copper (Cu), aluminum (Al), tungsten (W), titanium (Ti), tantalum (Ta), ruthenium (Ru), or manganese (Mn).

The wiring insulating layers in the wiring layer included in the semiconductor package may include, for example, silicon oxide, silicon nitride, silicon oxynitride, an insulating material having a dielectric constant lower than that of silicon oxide, or a combination thereof.

The insulating layers in the bonding layers included in the semiconductor package may include, for example, silicon oxide, silicon nitride, silicon oxynitride, an insulating material having a dielectric constant lower than that of silicon oxide, a polymer material, or a combination thereof. The polymer material may include, for example, benzocyclobutene (BCB), polyimide (PI), polybenzoxazole (PBO), silicon, acrylate, epoxy, etc.

The through-electrodes included in the semiconductor package may be formed of, for example, through silicon vias (TSVs). Each of the through-electrodes may include a conductive plug penetrating a substrate and a conductive barrier layer surrounding the conductive plug. For example, the conductive plug may have a cylindrical shape, and the conductive barrier layer may have a cylindrical shape surrounding the sidewall of the conductive plug. A via insulating layer may be interposed between each through-electrode and the substrate to surround the sidewall of the through-electrode. Each through-electrode may be formed in any one of a via-first, via-middle, or via-last structure. At least a portion of the through-electrodes included in the semiconductor package may be used as electrodes for transferring signals, and at least another portion of the through-electrodes included in the semiconductor package may be used as electrodes for transferring power.

At least a portion of the semiconductor chips included in the semiconductor package may be encapsulated using a first molding member 510 and a second molding member 520. For example, the semiconductor package may further include the first molding member 510 surrounding the first semiconductor chip 100 and the second molding member 520 surrounding the plurality of second semiconductor chips 200. The first and second molding members 510 and 520 included in the semiconductor package may include, for example, an organic molding member such as epoxy molding compound (EMC) and/or an inorganic molding members such as silicon oxide, silicon nitride, silicon oxynitride, an insulating material having a dielectric constant lower than that of silicon oxide, or a combination thereof.

The first molding member 510 surrounding the first semiconductor chip 100 and the second molding member 520 surrounding the plurality of second semiconductor chips 200 may be separated from each other by the first inter-chip bonding layers 410 and 420L interposed between the first semiconductor chip 100 and the plurality of second semiconductor chips 200. For example, in some aspects where the first inter-chip bonding layers 410 and 420L are formed by the hybrid bonding method, the first molding member 510 and the second molding member 520 may be separated from each other so that the first molding member 510 is disposed below the first bonding layer 410 and the second molding member 520 is disposed above the first bonding layer 410. In some embodiments, the first molding member 510 may include an inorganic molding member, and the second molding member 520 may include an organic molding member.

In some embodiments, the first molding member 510 surrounding the first semiconductor chip 100 and the second molding member 520 surrounding the plurality of second semiconductor chips 200 may be integrally formed using the same molding member. For example, in some embodiments in which the first inter-chip bonding layers 410 and 420L are connected together by the thermo-compression bonding method, the first molding member 510 and the second molding member 520 may be integrally formed using the same molding member. For example, in an embodiment, the first molding member 510 and the second molding member 520 may include the same organic molding member.

The semiconductor package may further include a package connection terminal 600 disposed below the first semiconductor chip 100. In some embodiments, the semiconductor package may include a plurality of the package connection terminals 600. In an embodiment, the package connection terminal 600 may be disposed below the power wiring layer 140 of the first semiconductor chip 100. In some embodiments, a redistribution layer may be interposed between the power wiring layer 140 of the first semiconductor chip 100 and the package connection terminal 600.

The package connection terminal 600 may be, for example, a solder ball, a bump, etc. At least a portion of the package connection terminals 600 may be electrically connected to at least a portion of the plurality of first through-electrodes 112 and used for transferring signals. In some embodiments, at least another portion of the package connection terminals 600 may be electrically connected to at least another portion of the plurality of first through-electrodes 112 and used for transferring power.

At least one of the first semiconductor chip 100 or the plurality of second semiconductor chips 200 may be a memory chip. That is, in some embodiments, the first semiconductor chip 100 may be a memory chip; in some embodiments, the first semiconductor chip 100 and one or more of the second semiconductor chips 200 may be memory chips; and in some embodiments, one or more of the second semiconductor chips 200 may be memory chip(s). For example, in an embodiment, the semiconductor package may be a high bandwidth memory (HBM), the first semiconductor chip 100 may be a buffer chip, a host chip, or a logic chip for controlling the plurality of second semiconductor chips 200, and the plurality of second semiconductor chips 200 may be memory chips including memory cells.

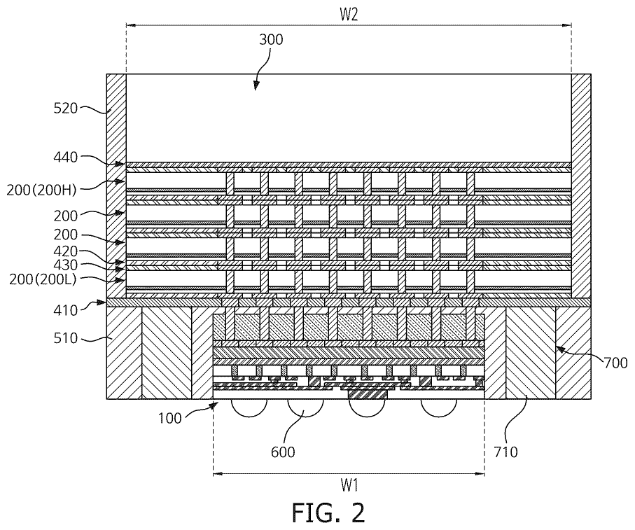

Referring to FIG. 2, the semiconductor package may further include one or more lower dummy chips 700 disposed at a periphery of the first semiconductor chip 100. For example, in some embodiments in which a width W1 of the first semiconductor chip 100 is less than a width W2 of each of the plurality of second semiconductor chips 200, the semiconductor package may include the one or more lower dummy chips 700 disposed on a side of the first semiconductor chip 100. In some embodiments, the one or more lower dummy chips 700 may support the plurality of second semiconductor chips 200 from below the plurality of second semiconductor chips 200. In an embodiment, the first inter-chip bonding layers 410 and 420L may be disposed on the first semiconductor chip 100 and the lower dummy chips 700, and the plurality of second semiconductor chips 200 may be stacked on the first inter-chip bonding layers 410 and 420L. The first semiconductor chip 100 and the lower dummy chips 700 may support the plurality of second semiconductor chips 200 from below the plurality of second semiconductor chips 200.

Each of the one or more lower dummy chips 700 may include a lower dummy substrate 710. For example, the lower dummy substrate 710 may include the same or similar material as or to the material (e.g., silicon, germanium, etc.) included in the upper dummy chip 300. In an embodiment, the lower dummy substrate 710 may be at least a portion of a bare wafer.

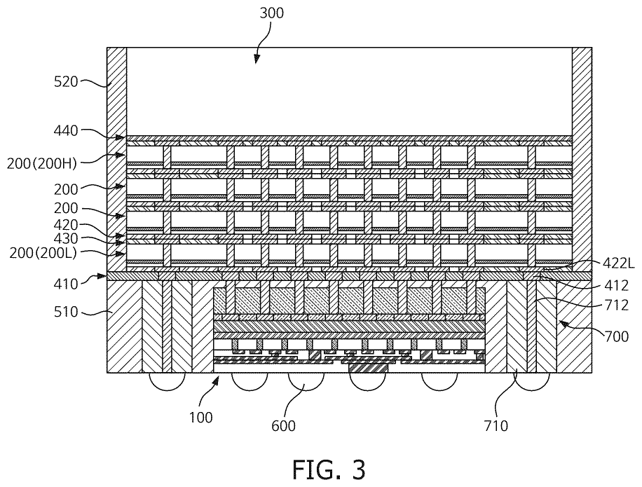

Referring to FIG. 3, at least one of the one or more lower dummy chips 700 may include a dummy through-electrode 712 penetrating the lower dummy substrate 710. The dummy through-electrode 712 may be electrically connected to at least a portion of the plurality of second through-electrodes 212.

For example, the first inter-chip bonding layers 410 and 420L may be interposed between the first semiconductor chip 100 and the one or more lower dummy chips 700, and the plurality of second semiconductor chips 200. That is, the first inter-chip bonding layers 410 and 420L may be interposed between the first semiconductor chip 100 and the plurality of second semiconductor chips 200, and between the one or more lower dummy chips 700 and the plurality of second semiconductor chips 200. A portion of the first inter-chip connection members 412 and 422L included in the first inter-chip bonding layers 410 and 420L may be electrically connected to the plurality of first through-electrodes 112 of the first semiconductor chip 100 and a portion of the plurality of second through-electrodes 212 of the lowermost second semiconductor chip 200L. A remaining portion of the first inter-chip connection members 412 and 422L included in the first inter-chip bonding layers 410 and 420L may be electrically connected to the dummy through-electrode 712 included in the lower dummy chip 700 and a remaining portion of the plurality of second through-electrodes 212 of the lowermost second semiconductor chip 200L.

In an embodiment, a portion of the first bonding pads 412 included in the first bonding layer 410 may be formed above the lower dummy chips 700 and may be electrically connected to the dummy through-electrodes 712. The second bonding pads 422L included in the lowermost second bonding layer 420L may be electrically connected to the plurality of second through-electrodes 212 included in the lowermost second semiconductor chip 200L. Among the second bonding pads 422L included in the lowermost second bonding layer 420L, the second bonding pad 422L facing the first bonding pad 412 electrically connected to the dummy through-electrode 712 may be coupled or connected to the first bonding pad 412 electrically connected to the first dummy through-electrode 712, thereby connecting the first inter-chip connection members 412 and 422L. Through the first inter-chip connection members 412 and 422L connected as described above, the dummy through-electrode 712 may be electrically connected to a portion of the plurality of second through-electrodes 212 of the lowermost second semiconductor chip 200L.

In an embodiment, a portion of the package connection terminals 600 may be electrically connected to the dummy through-electrodes 712. In some embodiments, power (and/or signals) may be transferred to the second semiconductor chips 200 through the package connection terminals 600, the dummy through-electrodes 712, and the first inter-chip connection members 412 and 422L. That is, according to some embodiments in which the dummy through-electrode 712 is formed in the lower dummy chip 700, an additional power (and/or signal) transmission passage may be secured.

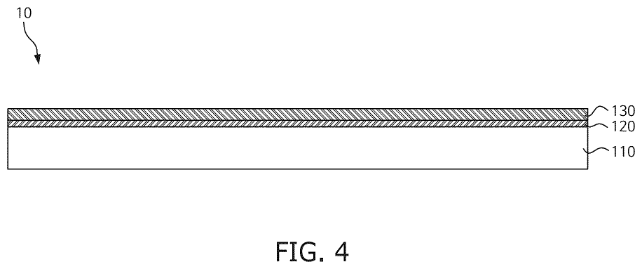

FIGS. 4 to 13 are diagrams illustrating an example of a process of manufacturing the first semiconductor chip 100, according to some embodiments.

Referring to FIG. 4, a first wafer 10 including the first semiconductor substrate 110, the first device layer 120 formed on the active side of the first semiconductor substrate 110, and the signal wiring layer 130 disposed on the first device layer 120 may be prepared.

The first semiconductor substrate 110 may include, for example, silicon or germanium, but embodiments are not limited thereto. For example, the first semiconductor substrate 110 may include a material having properties similar to silicon or germanium, such as silicon germanium, indium antimonide, lead telluride compound, indium arsenide, indium phosphide, gallium arsenide, gallium antimonide, etc. The first device layer 120 may include a semiconductor device. In some embodiments, the first device layer 120 may include various microelectronic devices, for example, a MOSFET such as a CMOS transistor, system LSI, flash memory, DRAM, SRAM, EEPROM, PRAM, MRAM, or RERAM, an imaging sensor such as a CIS, an MEMS, an active device, a passive device, etc.

The signal wiring layer 130 may include a signal wiring pattern through which signals are transferred and a power wiring pattern through which power (e.g., power, ground, etc.) is transferred.

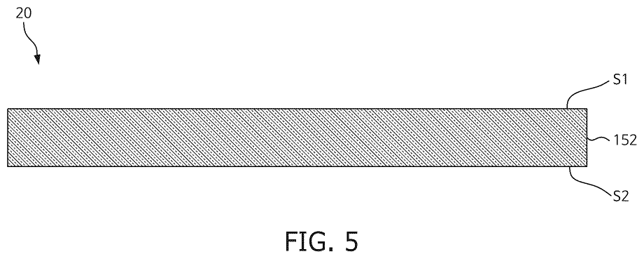

Referring to FIG. 5, a second wafer 20 including the compensation substrate 152 having a first side S1 and a second side S2 opposite to the first side S1 may be prepared.

The compensation substrate 152 may include the same or similar material as or to the material included in the first semiconductor substrate 110, such as silicon, germanium, etc. In some embodiments, the compensation substrate 152 may include a material having a higher thermal conductivity than a material (e.g., silicon, germanium, etc.) generally included in a semiconductor substrate.

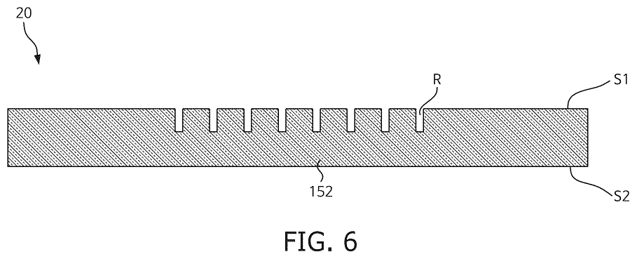

Referring to FIG. 6, a plurality of recesses R may be formed in the first side S1 of the compensation substrate 152 included in the second wafer 20. For example, a portion of the first side S1 of the compensation substrate 152 may be etched toward the second side S2, such that the plurality of recesses R are formed in the first side S1 of the compensation substrate 152.

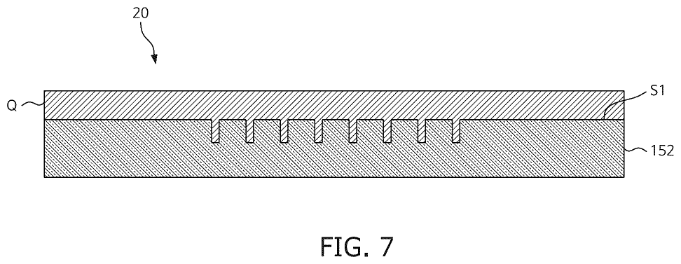

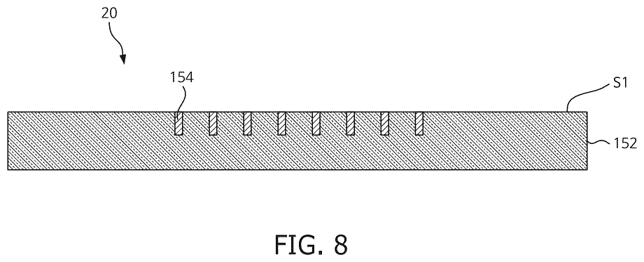

Referring to FIGS. 7 and 8, compensation through-electrodes 154 may be formed in the first side S1 of the compensation substrate 152 of the second wafer 20. For example, first, as illustrated in FIG. 7, a conductive member Q may be disposed on the first side S1 of the compensation substrate 152. Accordingly, the plurality of recesses R formed in the first side S1 of the compensation substrate 152 may be filled with the conductive member Q. As illustrated in FIG. 8, a portion of the conductive member Q may be removed (e.g., ground) to form the compensation through-electrodes 154 in the first side S1 of the compensation substrate 152, which penetrates a portion of a thickness of the compensation substrate 152.

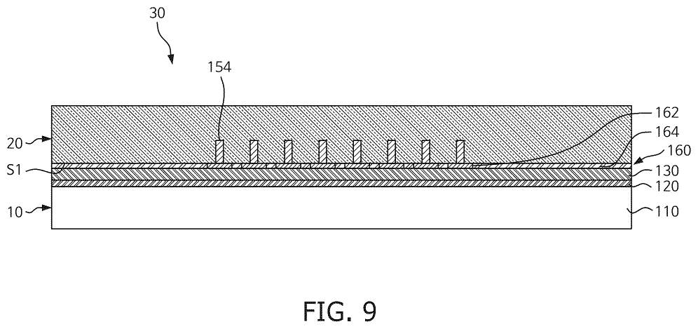

Referring to FIG. 9, the first wafer 10 including the first semiconductor substrate 110, the first device layer 120, and the signal wiring layer 130 may be bonded to the second wafer 20 having the compensation through-electrodes 154 formed in the first side S1 of the compensation substrate 152, thereby forming a third wafer 30. For example, the first wafer 10 and the second wafer 20 may be coupled with each other by the hybrid bonding method. Specifically, a bonding layer including a bonding pad and an insulating layer surrounding the bonding pad may be formed on the active side of the first wafer 10 (specifically, on the signal wiring layer 130). A bonding layer including a bonding pad and an insulating layer surrounding the bonding pad may be formed on the first side S1 of the compensation substrate of the second wafer 20. The second wafer 20 may be disposed on the first wafer 10 such that the bonding layer formed in the second wafer 20 faces the bonding layer formed in the first wafer 10 (i.e., the first side S1 of the compensation substrate 152 of the second wafer 20 faces the active side of the first semiconductor substrate 110 of the first wafer 10). The insulating layers of the first wafer 10 and the second wafer 20 facing each other may be expanded thermally to come into contact with each other, and atoms contained in the insulating layers may diffuse to bond, thereby forming the in-chip insulating layer 164. The bonding pads facing each other may be expanded thermally to come into contact with each other, and metal atoms contained in the bonding pads may diffuse to bond, thereby forming the in-chip connection members 162. That is, the in-chip bonding layer 160 may be formed by bonding the bonding layers formed in the first wafer 10 and the second wafer 20 to each other. Thus, the third wafer 30 including the first wafer 10, the second wafer 20, and the in-chip bonding layer 160 interposed between the two wafers 10 and 20 may be formed.

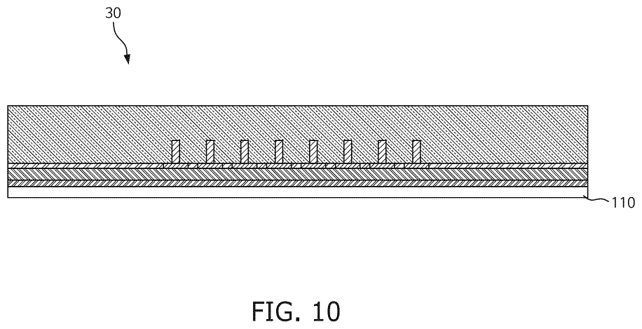

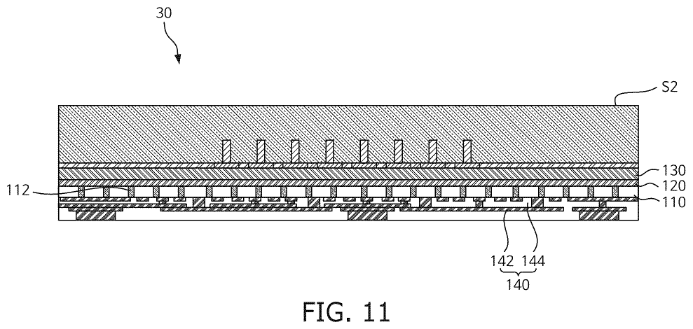

Referring to FIGS. 10 and 11, the plurality of first through-electrodes 112 and the power wiring layer 140 may be formed in the third wafer 30. For example, first, as illustrated in FIG. 10, the first semiconductor substrate 110 may be thinned. Specifically, a portion of the inactive side of the first semiconductor substrate 110 may be removed (e.g., ground, etched, polished, etc.). The plurality of first through-electrodes 112 penetrating the first semiconductor substrate 110 and the power wiring layer 140 disposed on the inactive side of the first semiconductor substrate 110 may be formed in the third wafer 30. The plurality of first through-electrodes 112 may be formed by a process similar to the process of forming the compensation through-electrodes 154 described above with reference to FIGS. 5 to 8. The power wiring layer 140 may include the power wiring pattern 142 and the power wiring insulating layer 144 surrounding the power wiring pattern 142, and may be formed by a wiring process (e.g., a wiring process including exposure, plating, etching, etc.) in the inactive side of the first semiconductor substrate 110.

The power wiring pattern 142 may be electrically connected to at least a portion of the semiconductor device of the first device layer 120 and/or at least a portion of the plurality of first through-electrodes 112 included in the first semiconductor substrate 110. The power wiring layer 140 may configure a back-side power delivery network (BSPDN). In this case, the power wiring pattern 142 may be electrically connected to the semiconductor device of the first device layer 120 through the first through-electrodes 112 and the buried power rail electrically connected to the first through-electrodes 112.

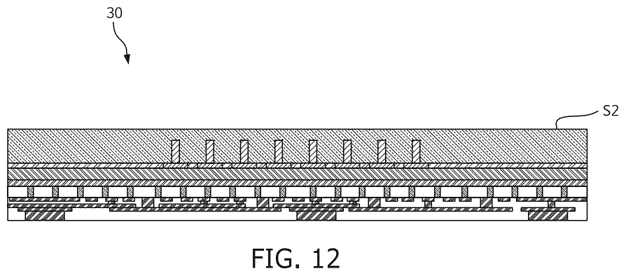

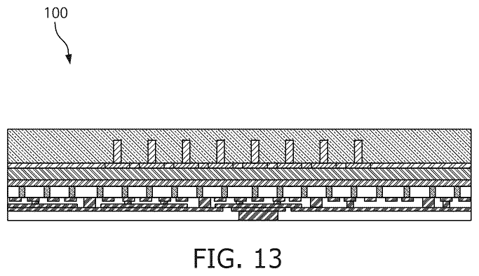

Referring to FIGS. 12 and 13, a plurality of first semiconductor chips 100 may be manufactured by dicing a third wafer 30. For example, first, as illustrated in FIG. 12, a portion of the compensation substrate (a portion of the second side S2) included in the third wafer 30 may be removed. The plurality of first semiconductor chips 100 may be manufactured by dicing the third wafer 30.

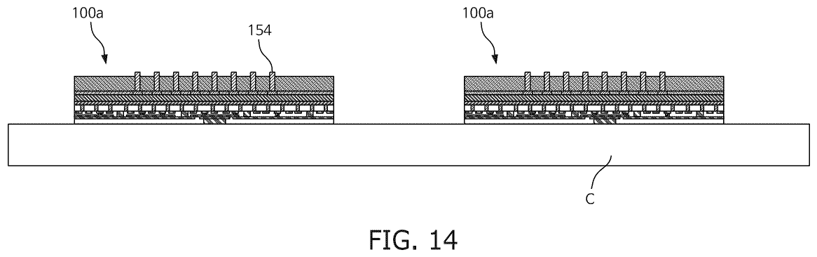

FIGS. 14 to 21 are diagrams illustrating an example of a process of manufacturing a semiconductor package, according to some embodiments.

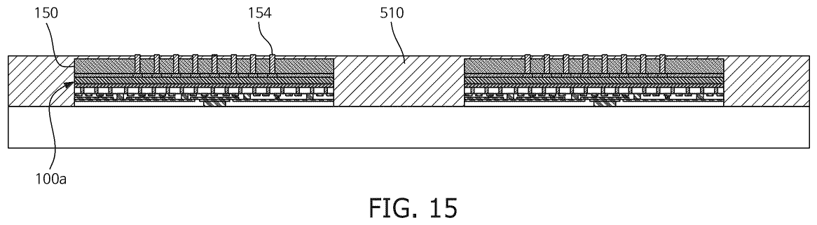

Referring to FIGS. 14 and 15, first semiconductor chips 100a may be encapsulated using the first molding member 510, and a portion of each of the compensation through-electrodes 154 of the first semiconductor chips 100a may be exposed upwards. For example, first, as illustrated in FIG. 14, the plurality of first semiconductor chips 100a may be disposed on a carrier C. The plurality of first semiconductor chips 100a disposed on the carrier C may be normal products among the semiconductor chips (100 of FIG. 13) diced from a wafer that have passed a test. In some embodiments, the semiconductor package manufacturing process may be performed on all of the plurality of first semiconductor chips 100a disposed on the carrier C, but in the following description, the semiconductor package manufacturing process will be described by focusing on only one first semiconductor chip 100a for convenience of explanation.

A portion of each of the compensation through-electrodes 154 may be exposed from the first semiconductor chip 100a disposed on the carrier C. For example, a portion of an upper surface of the first semiconductor chip 100a may be removed (e.g., ground, etched, polished, etc.) to expose a portion of each of the compensation through-electrodes 154 included in the first semiconductor chip 100a upwards.

As illustrated in FIG. 15, the first semiconductor chip 100a may be encapsulated to be surrounded by the first molding member 510. The first molding member 510 may include an inorganic molding member. For example, the first molding member 510 may include an inorganic molding member such as silicon oxide, silicon nitride, silicon oxynitride, an insulating material having a dielectric constant lower than that of silicon oxide, or a combination thereof, but embodiments are not limited thereto. A portion of each of the compensation through-electrodes 154 may be exposed upwards from the first semiconductor chip 100a again. For example, by selectively removing the first molding member 510 on the first semiconductor chip 100a and a portion (upper surface) of the compensation substrate 152 of the first semiconductor chip 100a by a chemical mechanical polishing (CMP) process, a portion of each of the compensation through-electrodes 154 may be exposed upwards from the first semiconductor chip 100a.

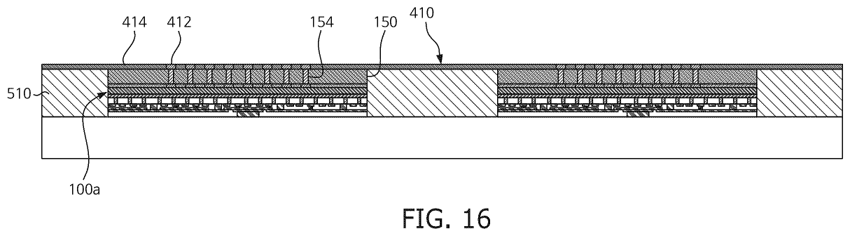

Referring to FIGS. 16 to 19, the plurality of second semiconductor chips 200 may be stacked on the first semiconductor chip 100a. Each of the plurality of second semiconductor chips 200 stacked on the first semiconductor chip 100a may include the second semiconductor substrate 210, the second device layer 220, and the wiring layer 230. The second semiconductor substrate 210 may include the same or similar material as or to a material of the first semiconductor substrate 110. The second device layer 220 may include a semiconductor device. In some embodiments, the second device layer 220 may include, for example, various microelectronic devices described above that may be included in the first device layer 120.

The lowermost second semiconductor chip 200L may be stacked on the first semiconductor chip 100a. The first semiconductor chip 100a and the lowermost second semiconductor chip 200L may be coupled with each other by the hybrid bonding method.

Specifically, as illustrated in FIG. 16, the first bonding layer 410 including the first bonding pads 412 and the first insulating layer 414 surrounding the first bonding pads 412 may be formed on the first semiconductor chip 100a (specifically, on the compensation layer 150) and the first molding member 510. The first bonding pads 412 may be electrically connected to the compensation through-electrodes 154 of the first semiconductor chip 100a.

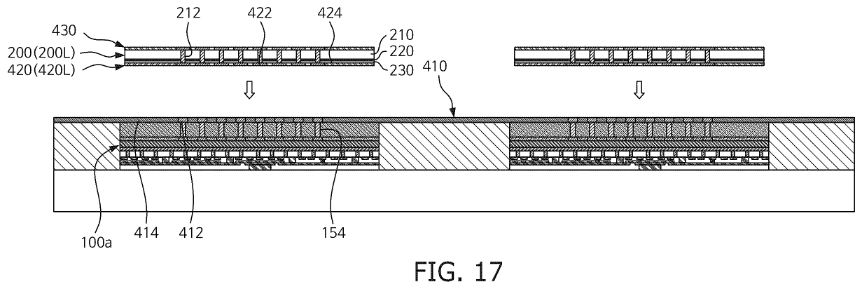

s illustrated in FIG. 17, the lowermost second bonding layer 420L including the second bonding pads 422 and the second insulating layer 424 surrounding the second bonding pad 422 may be formed below the lowermost second semiconductor chip 200L. The second bonding pads 422 may be electrically connected to the plurality of second through-electrodes 212 of the lowermost second semiconductor chip 200L.

The lowermost second semiconductor chip 200L may be disposed on the first semiconductor chip 100a such that the lowermost second bonding layer 420L formed on the lowermost second semiconductor chip 200L faces the first bonding layer 410 formed on the first semiconductor chip 100a. The first insulating layer 414 and the second insulating layer 424 facing each other may be bonded to form a first inter-chip insulating layer, and the first bonding pads 412 and the second bonding pads 422 facing each other may be bonded to form a first inter-chip connection member. That is, the first bonding layer 410 and the second bonding layer 420L may be bonded to each other to form a first inter-chip bonding layer. Thus, the first semiconductor chip 100a and the lowermost second semiconductor chip 200L may be coupled to each other.

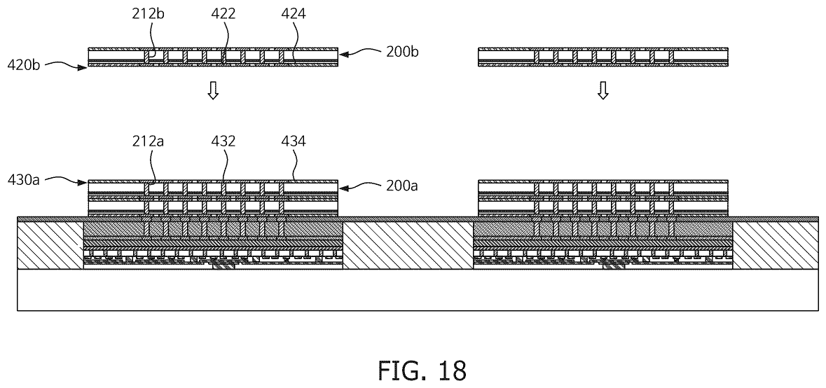

One or more second semiconductor chips 200 may be stacked on the lowermost second semiconductor chip 200L. For example, as illustrated in FIG. 18, a third bonding layer 430a including the third bonding pads 432 and the third insulating layer 434 surrounding the third bonding pads 432 may be formed above a second semiconductor chip 200a (hereinafter, “lower second semiconductor chip 200a”) disposed at a lower side among the two adjacent second semiconductor chips 200a and 200b. The third bonding pads 432 included in the third bonding layer 430a may be electrically connected to a plurality of second through-electrodes 212a of the lower second semiconductor chip 200a.

The second bonding layer 420b including the second bonding pads 422 and the second insulating layer 424 surrounding the second bonding pads 422 may be formed below a second semiconductor chip 200b (hereinafter, “upper second semiconductor chip 200b”) disposed at an upper side among the two adjacent second semiconductor chips 200a and 200b. The second bonding pads 422 included in the second bonding layer 420b may be electrically connected to a plurality of second through-electrodes 212b of the upper second semiconductor chip 200b.

The upper second semiconductor chip 200b may be disposed on the lower semiconductor chip 200a such that the second bonding layer 420b formed below the upper second semiconductor chip 200b faces the third bonding layer 430a formed above the lower second semiconductor chip 200a. The second insulating layer 424 and the third insulating layer 434 facing each other may be bonded to form a second inter-chip insulating layer, and the second bonding pads 422 and the third bonding pads 432 facing each other may be bonded to form a second inter-chip connection member. That is, the second bonding layer 420b and the third bonding layer 430a may be bonded to each other to form a second inter-chip bonding layer. Thus, the two second semiconductor chips 200a and 200b disposed adjacent to each other may be coupled to each other.

While it is described above that the semiconductor chips are coupled to each other by the hybrid bonding method, embodiments are not limited thereto. For example, in some embodiments, the semiconductor chips may be coupled with each other by any method such as thermo-compression bonding method etc.

The upper dummy chip 300 may be disposed on the plurality of second semiconductor chips 200. The upper dummy chip 300 may include the same or similar material as or to the material (e.g., silicon, germanium, etc.) included in the first semiconductor substrate 110 and the second semiconductor substrate 210. The upper dummy chip 300 may include only the same or similar material (e.g., silicon, germanium, etc.) as or to the material included in the first semiconductor substrate 110 and the second semiconductor substrate 210. For example, the upper dummy chip 300 may be at least a portion of a bare wafer.

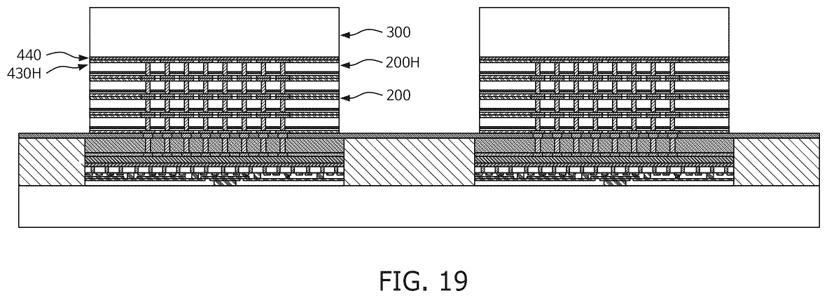

For example, as illustrated in FIG. 19, the uppermost third bonding layer 430H may be formed above the uppermost second semiconductor chip 200H, and the fourth bonding layer 440 may be formed below the upper dummy chip 300. The upper dummy chip 300 may be disposed on the uppermost second semiconductor chip 200H such that the fourth bonding layer 440 formed below the upper dummy chip 300 faces the uppermost third bonding layer 430H. The uppermost third bonding layer 430H and the fourth bonding layer 440 may be coupled or connected to each other, thereby coupling the uppermost second semiconductor chip 200H to the upper dummy chip 300.

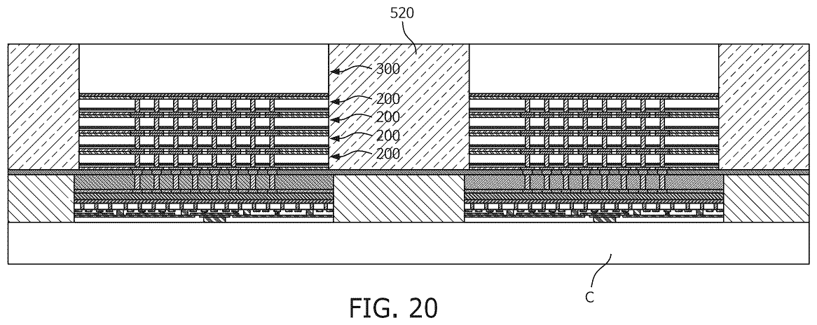

Referring to FIG. 20, the plurality of second semiconductor chips 200 and the upper dummy chip 300 may be encapsulated by the second molding member 520. The second molding member 520 may include an organic molding member. For example, in some embodiments, the second molding member 520 may include an organic molding member such as an epoxy molding compound (EMC), but embodiments are not limited thereto. The carrier C may be separated.

In FIGS. 15 to 20 and the above description, it has been illustrated and described that the first semiconductor chip 100a is encapsulated first, followed by the plurality of second semiconductor chips 200 and the upper dummy chip 300 being encapsulated separately, but embodiments are not limited thereto. For example, in some embodiments in which a separate connection terminal (e.g., a bump) is interposed between the first semiconductor chip 100a and the lowermost semiconductor chip 200L and the first semiconductor chip 100a and the lowermost semiconductor chip 200L are bonded to each other by the thermo-compression bonding method, the first semiconductor chip 100a, the second semiconductor chip 200, and the upper dummy chip 300 may be stacked sequentially, and then the first semiconductor chip 200, the plurality of second semiconductor chips 200, and the upper dummy chip 300 may be simultaneously encapsulated using the same molding member (e.g., an organic molding member).

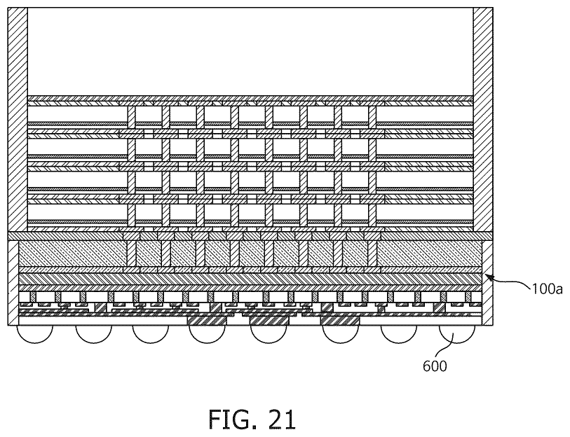

Referring to FIG. 21, the package connection terminals 600 may be attached to a lower portion of the first semiconductor chip 100a. In some embodiments, the package connection terminals 600 may be, for example, a solder ball, a bump, etc. Thus, a semiconductor package may be manufactured.

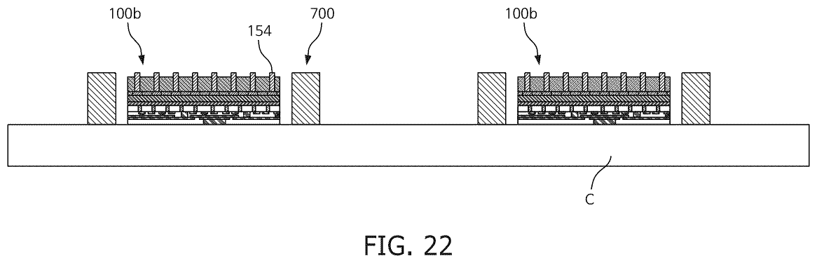

FIGS. 22 to 27 are diagrams illustrating an example of a process of manufacturing a semiconductor package, according to some embodiments.

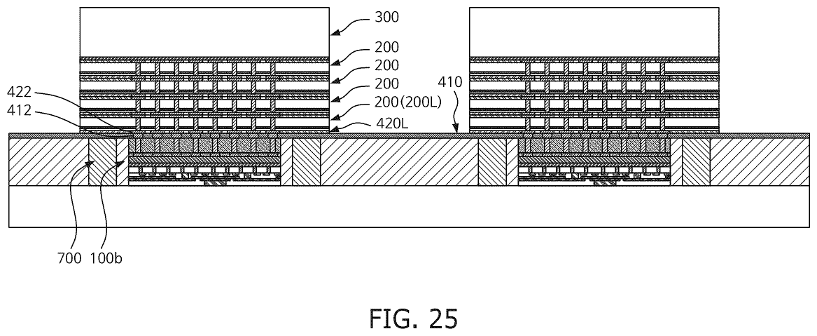

Referring to FIG. 22, a plurality of first semiconductor chips 100b may be disposed on a carrier C. The plurality of first semiconductor chips 100b disposed on the carrier C may be normal products among semiconductor chips (100 of FIG. 13) diced from a wafer that have passed a test. The widths of the plurality of first semiconductor chips 100b may be less than widths of a plurality of second semiconductor chips (200 of FIG. 25) to be disposed on each of the first semiconductor chips 100b.

In some embodiments, the semiconductor package manufacturing process may be performed on all of the plurality of first semiconductor chips 100b disposed on the carrier C, but in the following description, the semiconductor package manufacturing process will be described by focusing on only one first semiconductor chip 100b for convenience of explanation.

A portion of each of the compensation through-electrodes 154 may be exposed from the first semiconductor chip 100b disposed on the carrier. For example, a portion of an upper surface of the first semiconductor chip 100b may be removed (e.g., ground, etched, polished, etc.) to expose a portion of each of the compensation through-electrodes 154 included in the first semiconductor chip 100b upwards.

One or more lower dummy chips 700 may be disposed at a periphery (e.g., to a side) of the first semiconductor chip 100b on the carrier C. Although not illustrated, in some embodiments, the lower dummy chips 700 may each include a dummy through-electrode penetrating a lower dummy substrate. For example, the lower dummy substrate may include the same or similar material as or to the material (e.g., silicon, germanium, etc.) included in the upper dummy chip 300. As a specific example, in some embodiments, the lower dummy substrate may be at least a portion of a bare wafer.

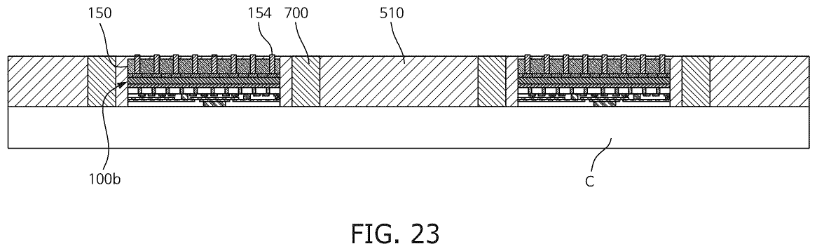

Referring to FIG. 23, the first semiconductor chip 100b and the one or more lower dummy chips 700 may be encapsulated to be surrounded by the first molding member 510. The first molding member 510 may include an inorganic molding member. A portion of each of the compensation through-electrodes 154 may be exposed upwards from the first semiconductor chip 100b again. For example, by selectively removing the first molding member 510 on the first semiconductor chip 100b and a portion (upper surface) of the compensation substrate 150 of the first semiconductor chip 100b by a chemical mechanical polishing (CMP) process, a portion of each of the compensation through-electrodes 154 may be exposed upward from the first semiconductor chip 100b.

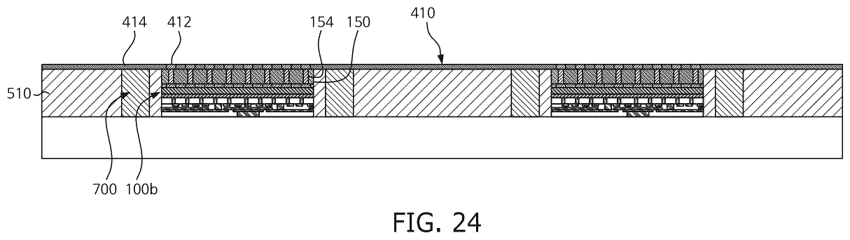

Referring to FIGS. 24 and 25, the plurality of second semiconductor chips 200 and the upper dummy chip 300 may be stacked on the first semiconductor chip 100b and the one or more lower dummy chips 700. The process of stacking the plurality of second semiconductor chips 200 and the upper dummy chip 300 on the first semiconductor chip 100b and the one or more lower dummy chips 700 may be performed similarly to the process described above with reference to FIGS. 16 to 19.

Briefly, as illustrated in FIG. 24, the first bonding layer 410 including the first bonding pads 412 and the first insulating layer 414 surrounding the first bonding pads 412 may be formed on the first semiconductor chip 100b and the one or more lower dummy chips 700. The first bonding pads 412 may be electrically connected to the compensation through-electrodes 154 of the first semiconductor chip 100b.

According to some embodiments in which the lower dummy chip 700 includes a dummy through-electrode, a portion of the first bonding pads 412 may be formed on the first semiconductor chip 100b to be electrically connected to the compensation through-electrodes 154, and a remaining portion of the first bonding pads 412 may be formed on the one or more lower dummy chips 700 to be electrically connected to the dummy through-electrodes of the one or more lower dummy chips 700.

As illustrated in FIG. 25, the plurality of second semiconductor chips 200 and the upper dummy chip 300 may be stacked on the first semiconductor chip 100b and the one or more lower dummy chips 700.

According to some embodiments in which the lower dummy chip 700 includes a dummy through-electrode, the dummy through-electrode may be electrically connected to a portion of the plurality of second through-electrodes included in the lowermost second semiconductor chip 200L through the first inter-chip connection members 412 and 422 formed in the first inter-chip bonding layers 410 and 420L.

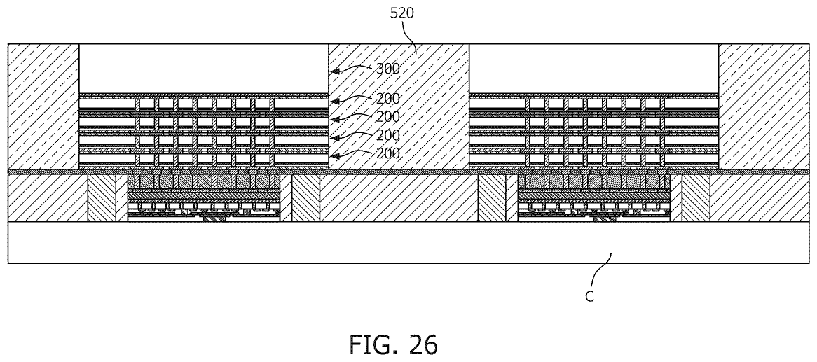

Referring to FIG. 26, the plurality of second semiconductor chips 200 and the upper dummy chip 300 may be encapsulated by the second molding member 520. The second molding member 520 may include an organic molding member. The carrier C may be separated.

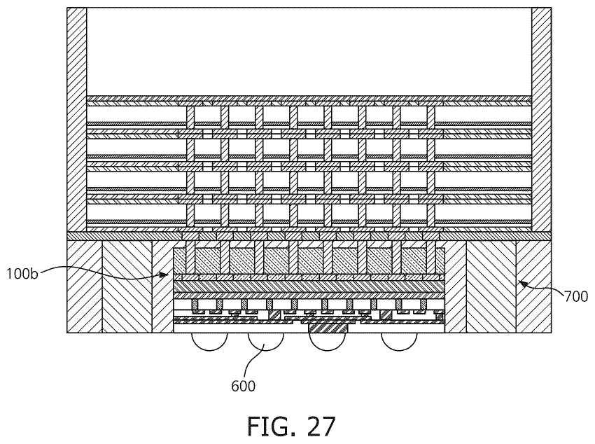

Referring to FIG. 27, the package connection terminals 600 may be attached to a lower portion of the first semiconductor chip 100b. According to some embodiments in which dummy through-electrodes are formed in the one or more lower dummy chips 700, a portion of the package connection terminals 600 may be attached to the lower portion of the first semiconductor chip 100b, and a remaining portion of the package connection terminals 600 may be attached to the lower portion of the one or more lower dummy chips 700.

Thus, a semiconductor package may be manufactured.

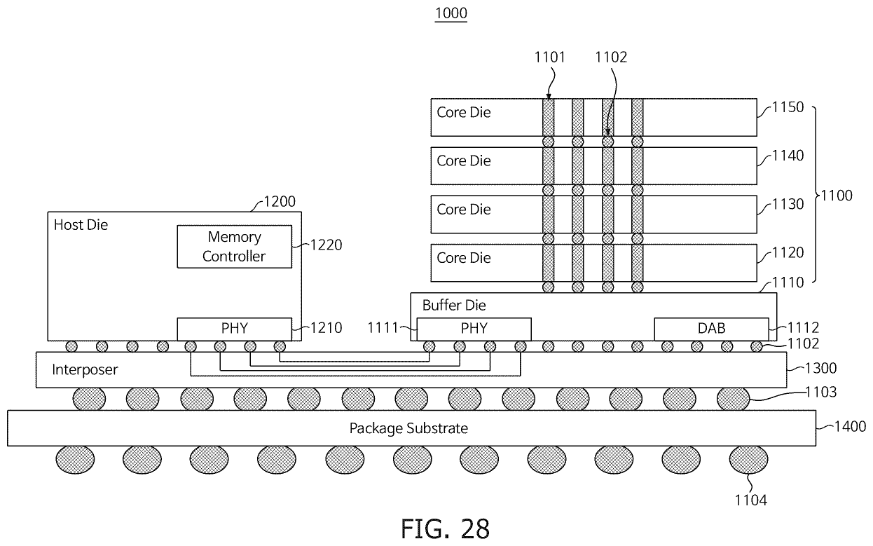

FIG. 28 is a diagram illustrating an example of a semiconductor package, according to some embodiments. A semiconductor system may include a semiconductor package 1000. Referring to FIG. 28, the semiconductor package 1000 may include a stacked memory device 1100, a host die 1200, an interposer 1300, and a package substrate 1400. The stacked memory device 1100 may include a buffer die 1110 and core dies 1120 to 1150. Each of the core dies 1120 to 1150 may include a memory cell array. The stacked memory device 1100 of the semiconductor package 1000 may include at least a portion of the semiconductor package having the structure described above with reference to FIGS. 1 to 3.

The buffer die 1110 may include a physical layer (PHY) 1111 and a direct access region (DAB) 1112. The physical layer 1111 may be electrically connected to a physical layer (PHY) 1210 of the host die 1200 through the interposer 1300. The stacked memory device 1100 may receive signals from the host die 1200 or transmit signals to the host die 1200 through the physical layer 1111.

The direct access region 1112 may provide an access path to transmit and receive signals to and from the stacked memory device 1100 without passing through the host die 1200. The direct access region 1112 may include conductive means (e.g., ports or pins) capable of direct communication with an external device (e.g., a test device). Signals and data received through the direct access region 1112 may be transmitted to the core dies 1120 to 1150 through TSVs. Data read from the core dies 1120 to 1150 for control of the core dies 1120 to 1150 may be transmitted to an external device through TSVs and the direct access region 1112. Accordingly, direct access and control of the core dies 1120 to 1150 may be performed.

The buffer die 1110 and the core dies 1120 to 1150 may be electrically connected to each other through TSVs 1101 and bumps 1102. The buffer die 1110 may receive signals provided to each channel from the host die 1200 through the bumps 1102 allocated for each channel. For example, in some embodiments, the bumps 1102 may be micro-bumps. In some embodiments, the bumps 1102 may be replaced with other conductive connection members.

The host die 1200 may execute applications supported by the semiconductor package 1000 using the stacked memory device 1100. For example, the host die 1200 may include at least one processor of a central processing unit (CPU), an application processor (AP), a graphic processing unit (GPU), a neural processing unit (NPU), a tensor processing unit (TPU), a vision processing unit (VPU), an image signal Processor (ISP), and/or a digital signal processor (DSP) to execute specialized operations.

The host die 1200 may include the physical layer 1210 and a memory controller 1220. The physical layer 1210 may include input and output circuits for transmitting and receiving signals to and from the physical layer 1111 of the stacked memory device 1100. The host die 1200 may provide various signals to the physical layer 1111 through the physical layer 1210. The signals provided to the physical layer 1111 may be transmitted to the core dies 1120 to 1150 through interface circuits of the physical layer 1111 and the TSVs 1101.

The memory controller 1220 may control the overall operation of the stacked memory device 1100. The memory controller 1220 may transmit signals for controlling the stacked memory device 1100 to the stacked memory device 1100 through the physical layer 1210. Additionally or alternatively, the memory controller 1220 may be included in the buffer die 1110.

The interposer 1300 may connect the stacked memory device 1100 to the host die 1200. The interposer 1300 may connect the physical layer 1111 of the stacked memory device 1100 to the physical layer 1210 of the host die 1200, and may provide physical paths formed with conductive materials. Accordingly, the stacked memory device 1100 and the host die 1200 may be stacked on the interposer 1300 to transmit and receive signals to and from each other.

Bumps 1103 may be attached to an upper portion of the package substrate 1400, and a solder ball 1104 may be attached to a lower portion thereof. For example, the bumps 1103 may be flip-chip bumps. The interposer 1300 may be stacked on the package substrate 1400 through the bumps 1103. The semiconductor package 1000 may transmit and receive signals to and from other external packages or semiconductor devices through the solder ball 1104. For example, the package substrate 1400 may be a printed circuit board (PCB).

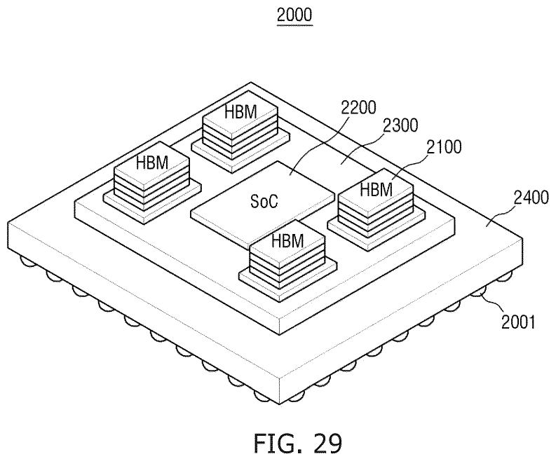

FIG. 29 is a diagram illustrating an example of implementation of a semiconductor package, according to some embodiments. Referring to FIG. 29, a semiconductor package 2000 may include a plurality of stacked memory devices 2100 and a host die 2200. The stacked memory devices 2100 and the host die 2200 may be stacked on an interposer 2300, and the interposer 2300 may be stacked on a package substrate 2400. The semiconductor package 2000 may transmit and receive signals to and from other external packages or semiconductor devices through a solder ball 2001 attached to the lower portion of the package substrate 2400.

Each of the stacked memory devices 2100 may be implemented based on HBM standard. However, embodiments are not limited thereto, and each of the stacked memory devices 2100 may be implemented based on a graphics double data rate (GDDR), a hybrid memory tube (HMC), or a wide I/O standard. Each of the stacked memory devices 2100 may correspond to the stacked memory device 1100 of FIG. 28.

The host die 2200 may be implemented as a system on chip (SoC) including at least one processor such as a CPU, an AP, a GPU, and/or an NPU. The host die 2200 may correspond to the host die 1200 of FIG. 28.

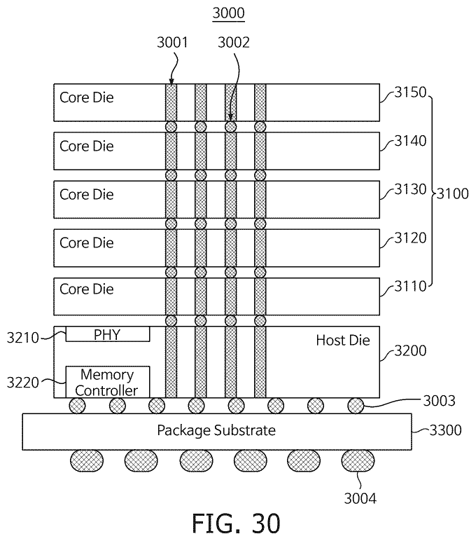

FIG. 30 is a diagram illustrating an example of a semiconductor package, according to some embodiments. Referring to FIG. 30, a semiconductor package 3000 may include a stacked memory device 3100, a host die 3200, and a package substrate 3300. The stacked memory device 3100 may include core dies 3110 to 3150. In some embodiments, each of the core dies 3110 to 3150 may include a memory cell array. In some embodiments, the semiconductor package 3000 may be a buffer-less semiconductor package. In this case, the host die 3200 may also perform the function of the buffer die. In some embodiments, at least one die (e.g., 3110 of FIG. 30) of the core dies 3110 to 3150 may be replaced with a buffer die. The stacked memory device 3100 and the host die 3200 of the semiconductor package 3000 may include at least a portion of the semiconductor package having the structure described above with reference to FIGS. 1 to 3.

The host die 3200 may include a physical layer 3210 for communicating with the stacked memory device 3100 and a memory controller 3220 for controlling the overall operation of the stacked memory device 3100. The host die 3200 may include a processor for controlling the overall operation of the semiconductor package 3000 and executing an application supported by the semiconductor package 3000. For example, the host die 3200 may include at least one processor such as a CPU, an AP, a GPU, and/or an NPU.

The stacked memory device 3100 may be disposed on the host die 3200 based on TSVs 3001 and stacked vertically on the host die 3200. Accordingly, the core dies 3110 to 3150 and the host die 3200 may be electrically connected to each other through the TSVs 3001 and bumps 3002 without an interposer. For example, the bumps 3002 may be micro-bumps. In another aspect, the bumps 3002 may be replaced with other conductive connection members.

Bumps 3003 may be attached to an upper portion of the package substrate 3300, and a solder ball 3004 may be attached to a lower portion thereof. For example, the bumps 3003 may be flip-chip bumps. The host die 3200 may be stacked on the package substrate 3300 through the bumps 3003. The semiconductor package 3000 may transmit and receive signals to and from other external packages or semiconductor devices through the solder ball 3004.

Certain embodiments have been described above for purposes of illustration only, and those skilled in the art with ordinary knowledge of the present disclosure will be able to make various modifications, changes and additions within the spirit and scope of the present disclosure, and such modifications, changes and additions should be construed to be included in a scope of the claims.

It should be understood that those of ordinary skill in the art to which the present disclosure pertains can make various substitutions, modifications and changes to the various embodiments based on the various embodiments described above, without departing from the technical spirit of the present disclosure, and thus, embodiments are not limited by the aspects described above and the accompanying drawings and all such substitutions, modifications and changes to the various embodiments described above are intended to be included in the scope of the appended claims.

What is claimed is:

1. A semiconductor package comprising:
a first semiconductor chip comprising a first semiconductor substrate having an active side and an inactive side opposite to the active side, a plurality of first through-electrodes penetrating the first semiconductor substrate, a power wiring pattern disposed on the inactive side of the first semiconductor substrate and connected to at least a portion of the plurality of first through-electrodes, and a compensation layer disposed on the active side of the first semiconductor substrate; and
a plurality of second semiconductor chips disposed on the first semiconductor chip, each of the plurality of second semiconductor chips comprising a second semiconductor substrate,
wherein:
the compensation layer comprises a compensation substrate, and a compensation through-electrodes that penetrate the compensation substrate and that are electrically connected to at least a portion of the plurality of first through-electrodes,
each of the plurality of second semiconductor chips comprises a plurality of second through-electrodes that penetrate the second semiconductor substrate, and
at least a portion of the plurality of first through-electrodes is electrically connected to at least a portion of the plurality of second through-electrodes through the compensation through-electrodes.

2. The semiconductor package of claim 1, wherein:
the first semiconductor chip further comprises an in-chip bonding layer between the compensation layer and the first semiconductor substrate, and
the in-chip bonding layer comprises:
an in-chip connection member that electrically connects the compensation through-electrodes to the at least a portion of the plurality of first through-electrodes; and
an in-chip insulating layer surrounding the in-chip connection member.

3. The semiconductor package of claim 1, further comprising a first bonding layer and a second bonding layer between the first semiconductor chip and the plurality of second semiconductor chips,
wherein:
the first bonding layer comprises:
first bonding pads electrically connected to the compensation through-electrodes; and
a first insulating layer surrounding the first bonding pads,
the second bonding layer comprises:
second bonding pads electrically connected to the plurality of second through-electrodes of the plurality of second semiconductor chips; and
a second insulating layer surrounding the second bonding pads, and
the first bonding pads and the second bonding pads electrically connect the compensation through-electrodes to the at least a portion of the plurality of second through-electrodes of the plurality of second semiconductor chips.

4. The semiconductor package of claim 1, further comprising a second bonding layer and a third bonding layer interposed between two adjacent second semiconductor chips of the plurality of second semiconductor chips,
wherein:
the second bonding layer comprises:
second bonding pads electrically connected to the plurality of second through-electrodes of the plurality of second semiconductor chips; and
a second insulating layer surrounding the second bonding pads,
the third bonding layer comprises:
third bonding pads electrically connected to the plurality of second through-electrodes of the plurality of second semiconductor chips; and
a third insulating layer surrounding the third bonding pads, and
the second bonding pads and the third bonding pads electrically connect, among the plurality of second semiconductor chips, the plurality of second through-electrodes of the two adjacent second semiconductor chips to each other.

5. The semiconductor package of claim 1, further comprising:
a first molding member surrounding the first semiconductor chip; and
a second molding member surrounding the plurality of second semiconductor chips.

6. The semiconductor package of claim 5, wherein:
the first molding member comprises an inorganic molding member, and
the second molding member comprises an organic molding member.

7. The semiconductor package of claim 6, further comprising a bonding layer between the first semiconductor chip and the plurality of second semiconductor chips,
wherein:
the first molding member is disposed below the bonding layer, and
the second molding member is disposed above the bonding layer.

8. The semiconductor package of claim 5, wherein each of the first molding member and the second molding member comprises an organic molding member.

9. The semiconductor package of claim 1, wherein the compensation substrate comprises silicon or germanium.

10. The semiconductor package of claim 1, wherein a width of at least one of the compensation through-electrodes is greater than a width of at least one of the plurality of first through-electrodes or a width of at least one of the plurality of second through-electrodes.

11. The semiconductor package of claim 1, wherein a length of at least one of the compensation through-electrodes is greater than a length of at least one of the plurality of first through-electrodes or a length of at least one of the plurality of second through-electrodes.

12. The semiconductor package of claim 1, wherein:
a width of the first semiconductor chip is less than a width of each of the plurality of second semiconductor chips,
the semiconductor package further comprises one or more lower dummy chips disposed at a periphery of the first semiconductor chip, and
the one or more lower dummy chips support the plurality of second semiconductor chips from below the plurality of second semiconductor chips.

13. The semiconductor package of claim 12, wherein each of the one or more lower dummy chips comprises silicon or germanium.

14. The semiconductor package of claim 12, wherein each of the one or more lower dummy chips comprises:
a lower dummy substrate; and
a dummy through-electrode that penetrates the lower dummy substrate and electrically connects to at least a portion of the plurality of second through-electrodes.

15. The semiconductor package of claim 14, further comprising a first bonding layer and a second bonding layer between the first semiconductor chip and the plurality of second semiconductor chips, and between the one or more lower dummy chips and the plurality of second semiconductor chips,
wherein:
the first bonding layer comprises:
a plurality of first bonding pads; and
a first insulating layer surrounding the plurality of first bonding pads, the second bonding layer comprises:
a plurality of second bonding pads electrically connected to the plurality of second through-electrodes of the plurality of second semiconductor chips; and
a second insulating layer surrounding the plurality of second bonding pads,
a portion of the plurality of first bonding pads and a portion of the plurality of second bonding pads electrically connect the compensation through-electrodes to a portion of the plurality of second through-electrodes, and
a remaining portion of the plurality of first bonding pads and a remaining portion of the plurality of second bonding pads electrically connect the dummy through-electrode of the one or more lower dummy chips to a remaining portion of the plurality of second through-electrodes.

16. The semiconductor package of claim 1, wherein the plurality of second semiconductor chips are disposed such that an active side of the second semiconductor substrate of each of the plurality of second semiconductor chips faces the active side of the first semiconductor substrate.

17. The semiconductor package of claim 1, further comprising an upper dummy chip disposed on the plurality of second semiconductor chips.

18. A semiconductor package comprising:
a first semiconductor chip comprising a first semiconductor substrate having an active side and an inactive side opposite to the active side, a plurality of first through-electrodes penetrating the first semiconductor substrate, a power wiring pattern disposed on the inactive side of the first semiconductor substrate and connected to at least a portion of the plurality of first through-electrodes, and a compensation layer disposed on the active side of the first semiconductor substrate;
a plurality of second semiconductor chips disposed on the first semiconductor chip, each of the plurality of second semiconductor chips comprising a second semiconductor substrate; and
a first inter-chip bonding layer between the first semiconductor chip and the plurality of second semiconductor chips,
wherein:
the compensation layer comprises a compensation substrate, and compensation through-electrodes that penetrate the compensation substrate and that are electrically connected to at least a portion of the plurality of first through-electrodes,
each of the plurality of second semiconductor chips comprises a plurality of second through-electrodes that penetrate the second semiconductor substrate,
the first inter-chip bonding layer comprises:
first inter-chip connection members that electrically connect the compensation through-electrodes to at least a portion of the plurality of second through-electrodes; and
a first inter-chip insulating layer surrounding the first inter-chip connection members, and
at least a portion of the plurality of first through-electrodes is electrically connected to at least a portion of the plurality of second through-electrodes through the compensation through-electrodes and the first inter-chip connection members.

19. The semiconductor package of claim 18, further comprising a second inter-chip bonding layer between each of the plurality of second semiconductor chips,
wherein:
the second inter-chip bonding layer comprises:
second inter-chip connection members electrically connecting, among the plurality of second semiconductor chips, a plurality of second through-electrodes of two adjacent second semiconductor chips to each other; and
a second inter-chip insulating layer surrounding the second inter-chip connection members.

20. A semiconductor chip comprising:
a semiconductor substrate having an active side and an inactive side opposite to the active side;
a plurality of through-electrodes penetrating the semiconductor substrate;
a power wiring pattern disposed on the inactive side of the semiconductor substrate and connected to at least a portion of the plurality of through-electrodes; and
a compensation layer disposed on the active side of the semiconductor substrate,
wherein the compensation layer comprises a compensation substrate, and compensation through-electrodes that penetrate the compensation substrate and that are electrically connected to at least a portion of the plurality of through-electrodes.
